(19) United States
(12) Patent Application Publication
(10) Pub. No.: US 2025/0318414 A1
(43) Pub. Date: Oct. 9, 2025

(54) DISPLAY PROTECTIVE LAYER AND ELECTRONIC APPARATUS COMPRISING THE SAME

(71) Applicant: Samsung Display Co., Ltd., Yongin-si (KR)

(72) Inventors: Beomsoo Shin, Yongin-si (KR); Suji Park, Yongin-si (KR); Jiyun Park, Yongin-si (KR); Seulgee Lee, Yongin-si (KR); Ho Lim, Yongin-si (KR)

(73) Assignee: Samsung Display Co., Ltd., Yongin-si (KR)

(21) Appl. No.: 19/170,490

(22) Filed: Apr. 4, 2025

(30) Foreign Application Priority Data
Apr. 9, 2024 (KR) 10-2024-0047905

(51) Int. Cl. H10K 59/80; C03C 17/00; G02B 1/11; G02B 1/14; H10K 102/00

(52) U.S. Cl. CPC H10K 59/8791; C03C 17/007; G02B 1/11; G02B 1/14; C03C 2217/29; C03C 2217/73; H10K 2102/331

(57) ABSTRACT

A display protective layer includes a hard coating layer on a substrate, and an anti-reflective layer on the hard coating layer. The anti-reflective layer includes a first inorganic particle having a first refractive index and a second inorganic particle having a second refractive index, a surface of the first inorganic particle is coated with a fluorine-containing moiety, and the second refractive index is greater than the first refractive index.

### CROSS-REFERENCE TO RELATED APPLICATION(S)

This application claims priority to and benefits of Korean Patent Application No. 10-2024-0047905 under 35 U.S.C. § 119, filed on Apr. 9, 2024, in the Korean Intellectual Property Office (KIPO), the entire contents of which are incorporated herein by reference.

### BACKGROUND

### 1. Technical Field

Embodiments relate to a display protective layer and an electronic apparatus including the same.

### 2. Description of the Related Art

Organic light-emitting devices are self-emissive devices that have wide viewing angles, high contrast ratios, short response times, and excellent characteristics in terms of luminance, driving voltage, and response speed, compared to devices in the art.

In an organic light-emitting device, a first electrode is arranged on a substrate, and a hole transport region, an emission layer, an electron transport region, and a second electrode are sequentially arranged on the first electrode. Holes provided from the first electrode move toward the emission layer through the hole transport region, and electrons provided from the second electrode move toward the emission layer through the electron transport region. Carriers, such as holes and electrons, recombine in the emission layer to produce excitons. These excitons transit from an excited state to a ground state, thereby generating light.

Electronic apparatuses in which organic light-emitting devices are applied use polymer films with hard coatings applied onto windows and protective layers.

### SUMMARY

Embodiments include a display protective layer including an anti-reflective layer having a low specular component included (SCI) and an electronic apparatus including the same.

Additional aspects will be set forth in part in the description which follows and, in part, will be apparent from the description, or may be learned by practice of the embodiments of the disclosure.

According to an embodiment, the display protective layer may include
a hard coating layer on a substrate, and
   an anti-reflective layer on the hard coating layer,
   wherein the anti-reflective layer may include a first inorganic particle having a first refractive index and a second inorganic particle having a second refractive index,
   a surface of the first inorganic particle may be coated with a fluorine-containing moiety, and

The second refractive index may be greater than the first refractive index.

According to an embodiment, the first refractive index may be in a range of about 1.10 to about 1.40.

According to an embodiment, the second refractive index may be in a range of about 1.60 to about 2.00.

According to an embodiment, the anti-reflective layer may include an upper layer and a lower layer, the upper layer may include the first inorganic particle, and the lower layer may include the second inorganic particle.

According to an embodiment, the hard coating layer and the anti-reflective layer may be in direct contact with each other.

According to an embodiment, the anti-reflective layer may include an upper layer and a lower layer, the upper layer may include the first inorganic particle, the lower layer may include the second inorganic particle, and the hard coating layer and the lower layer may be in direct contact with each other.

According to an embodiment, the first inorganic particle may include hollow inorganic particles.

According to an embodiment, the first inorganic particle may include a metalloid or an oxide thereof.

According to an embodiment, the first inorganic particle may include B, Si, Ge, As, Sb, Te, a combination thereof, or an oxide thereof.

According to an embodiment, the second inorganic particle may include a transition metal or an oxide thereof.

According to an embodiment, the second inorganic particle may include Zr or an oxide thereof.

According to an embodiment, the first inorganic particle may have a diameter in a range of about 1 nm to about 200 nm.

According to an embodiment, the second inorganic particle may have a diameter in a range of about 0.5 nm to about 100 nm.

According to an embodiment, a thickness of the anti-reflective layer may be in a range of about 150 nm to about 500 nm.

According to an embodiment, a surface energy of an upper portion of the anti-reflective layer may be less than or equal to about 25 dyne/cm.

According to an embodiment, a specular component included (SCI) of the anti-reflective layer may be less than or equal to about 0.30.

According to an embodiment, an electronic apparatus may include the display protective layer.

According to an embodiment, a hollow inorganic particle may have
a refractive index in a range of about 1.10 to about 1.40, and
a surface of the hollow inorganic particle may be coated with a fluorine-containing moiety.

According to an embodiment, the hollow inorganic particle may include a metalloid or an oxide thereof.

According to an embodiment, a diameter of the hollow inorganic particle may be in a range of about 1 nm to about 200 nm.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic diagram showing immediately after applying a composition for forming an anti-reflective layer onto a hard coating layer according to an On Cell anti-reflective film process to form a display protective layer (substrate not shown) according to an embodiment.

FIG. 2 is a schematic diagram showing an anti-reflective layer applied according to FIG. 1 has been completed through drying, pre-baking, exposure, and post-baking processes.

FIG. 3 is a schematic diagram showing a hollow inorganic particle of which a surface is coated with a fluorine-containing moiety, according to an embodiment.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within #30%, 20%, 10%, 5% of the stated value.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

The anti-reflective film process may have disadvantages such as being expensive and not reworkable, so there is an urgent need to switch to an On Cell anti-reflective film process.

In the On Cell anti-reflective film process, a low refractive index layer and a high refractive index layer may be needed at the top to create a destructive interference layer, and two coatings may be required.

The film process may require one film attachment process, but the On Cell anti-reflective film process may require two cleaning-coating-baking processes, thereby increasing initial investment costs and lead time. In the On Cell anti-reflective film process, two materials that each may cause stains may be used, and thus stains may occur twice in case coated twice, and coating thickness uniformity may be poor.

According to an embodiment, the display protective layer may include:
a hard coating layer arranged on a substrate; and
an anti-reflective layer arranged on the hard coating layer,
wherein the anti-reflective layer may include a first inorganic particle having a refractive index A and a second inorganic particle having a refractive index B,
a surface of the first inorganic particle may be coated with a fluorine-containing moiety, and
the refractive index B may be greater than the refractive index A.

The anti-reflective layer may be formed by applying only once a composition including first inorganic particles with a refractive index A and second inorganic particles with a refractive index B onto the hard coating layer, and processing the composition such as drying, exposure, baking, and the like.

According to an embodiment, the refractive index A may be in a range of about 1.10 to about 1.40. For example, the refractive index A may be in a range of about 1.20 to about 1.30.

According to an embodiment, the refractive index B may be in a range of about 1.60 to about 2.00. For example, the refractive index B may be in a range of about 1.62 to about 1.70.

According to an embodiment, the anti-reflective layer may include an upper layer and a lower layer, the upper layer may include first inorganic particles, and the lower layer may include second inorganic particles. In an embodiment, a refractive index of the upper layer may be in a range of about 1.10 to about 1.40, a refractive index of the lower layer may be in a range of about 1.60 to about 2.00, and the refractive index B may be greater than the refractive index A. Accordingly, the display protective layer including the anti-reflective layer may have an appropriately low specular component included (SCI). The refractive index value of the hard coating layer may be between refractive index A and refractive index B. The upper and lower layers may include a polymer in addition to inorganic particles, and the polymer may have little effect on the refractive index. Therefore, the refractive index of the inorganic particle included in the upper and lower layers may be approximately equal to the refractive index of the corresponding layer.

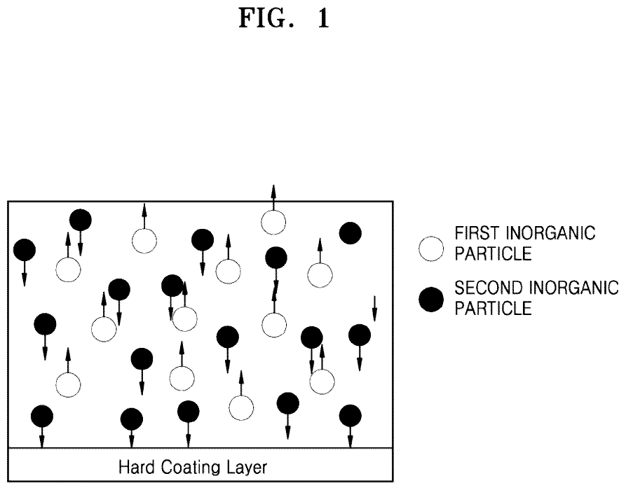

FIG. 1 is a schematic diagram showing immediately after applying a composition for forming an anti-reflective layer onto a hard coating layer according to an On Cell anti-reflective film process to form a display protective layer according to an embodiment (the substrate is not shown).

Referring to FIG. 1, the anti-reflective layer may include first inorganic particles and second inorganic particles each having different refractive indices, and a surface of the first inorganic particle may be coated with a fluorine-containing moiety. The first inorganic particle, of which the surface is coated with a fluorine-containing moiety, may be hydrophobic, and the second inorganic particle may be relatively hydrophilic. Since air is fundamentally hydrophobic, after the composition including the first inorganic particles and the second inorganic particles is applied onto the hard coating layer, the first inorganic particles may move to the top and the second inorganic particles may relatively move to the bottom.

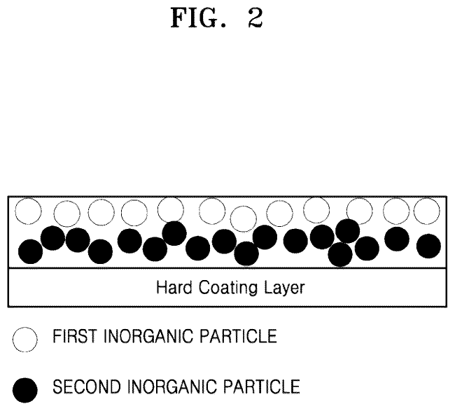

FIG. 2 is a schematic diagram showing an anti-reflective layer applied according to FIG. 1 has been completed through drying, pre-baking, exposure, and post-baking processes.

The composition including the first and second inorganic particles applied onto the hard coating layer may be dried, pre-baked, exposed, and post-baked to complete the anti-reflective layer.

According to an embodiment, the hard coating layer and the anti-reflective layer may be in direct contact with each other.

According to an embodiment, the anti-reflective layer may include an upper layer and a lower layer, the upper layer may include first inorganic particles, the lower layer may include second inorganic particles, and the hard coating layer and the lower layer may be in direct contact with each other.

According to an embodiment, an anti-reflective layer may be formed on the hard coating layer with only one coating step, and the anti-reflective layer may include a low refractive index layer and a high refractive index layer, so that the display protective layer including the anti-reflective layer may have an appropriately low SCI.

According to an embodiment, the first inorganic particles may include hollow inorganic particles. The term “hollow inorganic particles” used herein may be inorganic particles that have an empty space inside. According to an embodiment, the second inorganic particles may not include hollow inorganic particles.

According to an embodiment, the first inorganic particles may include a metalloid or an oxide thereof.

According to an embodiment, the first inorganic particles may include B, Si, Ge, As, Sb, Te, a combination thereof, or an oxide thereof. For example, the first inorganic particles may include an oxide of Si.

According to an embodiment, the second inorganic particles may include a transition metal or an oxide thereof. For example, the second inorganic particles may include Zr or an oxide thereof.

According to an embodiment, the second inorganic particle may be relatively more hydrophilic than the first inorganic particle. To increase the hydrophilicity of the second inorganic particle, the surface of the second inorganic particle may be modified by using a silicone resin or divalent acid.

According to an embodiment, a diameter of the first inorganic particle may be in a range of about 1 nm to about 200 nm. For example, the diameter of the first inorganic particle may be in a range of about 20 nm to about 150 nm. For example, the diameter of the first inorganic particle may be in a range of about 50 nm to about 100 nm.

According to an embodiment, a diameter of the second inorganic particle may be in a range of about 0.5 nm to about 100 nm. For example, the diameter of the second inorganic particle may be in a range of about 5 nm to about 50 nm. For example, the diameter of the second inorganic particle may be in a range of about 8 nm to about 30 nm.

According to an embodiment, a thickness of the substrate may be in a range of about 10,000 nm to about 70,000 nm.

For example, the thickness of the substrate may be in a range of about 20,000 nm to about 60,000 nm.

According to an embodiment, a thickness of the hard coating layer may in a range of be about 2,000 nm to about 8,000 nm. For example, the thickness of the hard coating layer may be in a range of about 3,000 nm to about 7,000 nm.

According to an embodiment, a thickness of the anti-reflective layer may be in a range of about 150 nm to about 500 nm. According to an embodiment, the anti-reflective layer may include an upper layer and a lower layer, the upper layer may include first inorganic particles, the lower layer may include second inorganic particles, and a thickness of the lower layer may be greater than a thickness of the upper layer. For example, the thickness of the upper layer of the anti-reflective layer may be in a range of about 50 nm to about 250 nm. For example, the thickness of the lower layer of the anti-reflective layer may be in a range of about 100 nm to about 300 nm.

Considering the protection of a display device, for example, a light-emitting device, which is the purpose of the display protective layer, the thicknesses of the substrate and the hard coating layer in the display protective layer may be within the above range.

In case that the positions of the upper layer, lower layer, and hard coating layer, the refractive index value, and thickness of each layer are as described above, the display protective layer according to an embodiment may have an appropriately low SCI.

According to an embodiment, the SCI of the anti-reflective layer may be less than or equal to about 0.30.

According to an embodiment, a surface energy of the upper portion of the anti-reflective layer may be less than or equal to about 25 dyne/cm. As a result, the upper portion of the anti-reflective layer may have liquid repellency.

According to an embodiment, the substrate may include glass or a polymer film.

The polymer film may include, for example, polyethylene terephthalate (PET), polyethylene naphthalate (PEN), ployimide (PI), and the like.

The glass may be, for example, rigid glass, thin-glass, or ultra-thin glass.

According to an embodiment, the hard coating layer may include an acrylate-based compound, for example, urethane acrylate or a polyester acrylate-based polymer.

According to an embodiment, the hard coating layer may include a polymer including a fluorine group or a silicon group. In an embodiment, the hard coating layer may include a polymer including a fluorine group. In an embodiment, the hard coating layer may include a polymer including a silicon group. In an embodiment, the hard coating layer may include a polymer including a fluorine group and a silicon group.

According to an embodiment, the hard coating layer may include a polymer including a perfluoropolyether moiety, a polytetrafluoroethylene moiety, a fluorinated ethylene propylene moiety, a perfluoroalkyl vinyl ether moiety, or a combination thereof.

According to an embodiment, the hard coating layer may include a polysiloxane polymer. In an embodiment, the polysiloxane polymer may be a typical organopolysiloxane polymer. In the organopolysiloxane polymer, an organic group may bind to a silicon portion that does not bind to an oxygen atom.

According to an embodiment, an electronic apparatus may include a display protective layer.

According to an embodiment, a hollow inorganic particle may have a refractive index in a range of about 1.10 to about 1.40, and the surface of the hollow inorganic particle may be coated with a fluorine-containing moiety.

According to an embodiment, the hollow inorganic particles may include a metalloid or an oxide thereof.

According to an embodiment, a diameter of the hollow inorganic particle may be in a range of about 1 nm to about 200 nm.

The description of the hollow inorganic particles may be referred to the description of the first inorganic particles described above. For example, the hollow inorganic particles may include B, Si, Ge, As, Sb, Te, a combination thereof, or an oxide thereof. For example, the hollow particles may include an oxide of Si.

The fluorine-containing moiety may include a C₁-C₈alkylene moiety and a C₂-C₁₅ perfluoroalkyl moiety. For example, the fluorine-containing moiety may include an ethylene moiety and a heptadecafluorooctyl moiety.

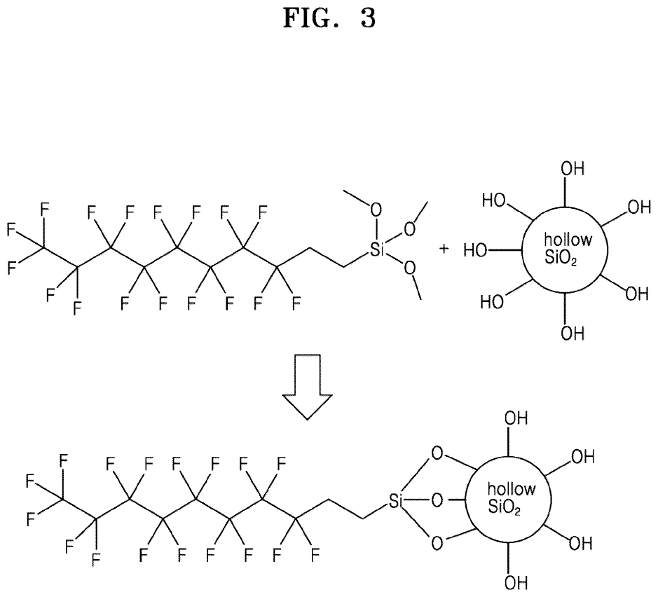

FIG. 3 is a schematic diagram showing a hollow inorganic particle, of which a surface is coated with a fluorine-containing moiety, according to an embodiment. In FIG. 3, the by-product 3CH₃OH is omitted.

Referring to FIG. 3, a surface of the hollow silica particle may be reacted with a (3,3,4,4,5,5,6,6,7,7,8,8,9,9,10,10,10-heptadecafluorodecyl)trimethoxysilane, so that the surface of the hollow silica particle may be coated with a fluorine-containing moiety.

According to an embodiment, the surface of the hollow silica may be coated with a fluorine-containing moiety, thereby making the hollow silica hydrophobic, and in case that a composition including the first inorganic particles and the second inorganic particles is applied onto the hard coating layer at a desired thickness, the hollow silica may spontaneously move upward. Afterwards, by applying drying, exposure, and baking processes, the upper layer of the anti-reflective layer including the hollow silica may have a relatively low refractive index.

According to an embodiment, the composition including first inorganic particles with a refractive index A and second inorganic particles with a refractive index B may further include a fluorine-containing oligomer, a crosslinkable monomer, a crosslinkable oligomer, an initiator, a solvent, or a combination thereof. For example, the crosslinkable monomer and crosslinkable oligomer may each independently include fluorine.

### DEFINITION OF TERMS

The term “C₁-C₆₀ alkyl group” as used herein may be a linear or branched aliphatic hydrocarbon monovalent group that has 1 to 60 carbon atoms, and examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, and the like. The term “C₁-C₆₀ alkylene group” as used herein may be a divalent group having a same structure as the C₁-C₆₀ alkyl group.

The number of carbon atoms in the substituent definition is not limited. For example, the maximum carbon number of 60 in a C₁-C₆₀ alkyl group is exemplary, and the definition for an alkyl group may apply equally to a C₂-C₁₅ alkyl group. The same applies to other cases.

The term “perfluoro” may mean that all hydrogens in a compound have been replaced with fluorine.

The spatially relative terms “below,” “beneath,” “lower,” “above,” and “upper” may be used to readily describe a relationship between one element or component and another element or component as illustrated in the drawings. It should be understood that spatially relative terms are intended to encompass different directions of a device in use or operation in addition to the direction depicted in the drawings. In an embodiment, in case that a device illustrated in the drawing is turned over, a device described as being placed “below” or “beneath” another device may be placed “above” the another device. Accordingly, the term “below” may include both the downward direction and the upward direction. The device may be oriented in other directions, and thus spatially relative terms may be interpreted according to the orientation.

Hereinafter, a display protective layer according to an embodiment will be described in detail with reference to Examples.

### EXAMPLES

### Hollow Silica Surface Coating

### Example 1

50 wt % of a hollow silica [refractive index: 1.29, diameter: approximately 80 nm] and 5 wt % of (3,3,4,4,5,5,6,6,7,7,8,8,9,9,10,10,10-heptadecafluorodecyl)trimethoxysilane were mixed in THF as a solvent, and stirred at 65° C. for 3 hours to prepare a hollow silica with the surface coated with a fluorine-containing moiety (wt % is a relative value to the weight of the solvent).

### Manufacture of Display Protective Layer

### Example 2

A display protective layer was manufactured as follows.

First, a PET layer was formed at a thickness of 40 μm, and subsequently, urethane acrylate was UV-cured to form a hard coating layer at a thickness of 5 μm.

17 wt % of the hollow silica of Example 1, 25 wt % of ZrO₂ [refractive index: 1.63, diameter: about 10 nm], 2 wt % of polytetrafluorene [Mw: 5000], 1 wt % of perfluorinated ployether [Mw: 3000], 3 wt % of styrene, 5 wt % of benzophenone-based photoinitiator, and the remainder as a solvent, which is a mixture of methyl ethyl ketone and isopropyl alcohol (1:1 volume ratio), were mixed to form a composition. The composition was applied onto the hard coating layer at a thickness of 260 nm.

After 10 seconds, the composition was vacuum dried and pre-baked at 90° C. for 3 hours. The composition was exposed to UV (365 nm) at 5 J, and post-baked at 100° C. for 3 hours to form an anti-reflective layer on the hard coating layer with one coating, thereby manufacturing the display protective layer.

### Comparative Example 1

A display protective layer was manufactured in the same manner as in Example 2, except that a hollow silica with the surface not coated with a fluorine-containing moiety was used.

### Evaluation Example

### Measurement of Specular Component Included (SCI)

The SCI of the display protective layers manufactured in Example 2 and Comparative Example 1 were each measured and shown in Table 1 below.

The SCI was measured by using CM-3700D.

TABLE 1

| | Specular component |
|---|---|
| | included (SCI) |
| Example 2 | 0.26 |
| Comparative Example 1 | 0.32 |

As a result of measuring the thickness of the upper and lower layers of the anti-reflective layer of Example 2 by using a transmission electron microscope (TEM), the thickness of the upper layer was about 100 nm and the thickness of the lower layer was about 150 nm.

As a result of elemental analysis according to the depth of the anti-reflective layer by using X-ray Photo Electron Spectroscopy (XPS), it was confirmed that SiO₂ was detected in the upper layer and ZrO₂ was detected in the lower layer.

The surface energy of the upper portion of the anti-reflective layer was measured with KRUSS DSA-100, and the measured value was 24 dyne/cm.

Since the display protective layer according to an embodiment includes an anti-reflective layer that may be formed with one coating, it may cause less staining and may be more economical than in the case of including an anti-reflective layer that is formed with two coatings.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display protective layer comprising:
a hard coating layer on a substrate; and
an anti-reflective layer on the hard coating layer, wherein
the anti-reflective layer comprises a first inorganic particle having a first refractive index and a second inorganic particle having a second refractive index,
a surface of the first inorganic particle is coated with a fluorine-containing moiety, and
the second refractive index is greater than the first refractive index.

2. The display protective layer of claim 1, wherein the first refractive index is in a range of about 1.10 to about 1.40.

3. The display protective layer of claim 1, wherein the second refractive index is in a range of about 1.60 to about 2.00.

4. The display protective layer of claim 1, wherein
the anti-reflective layer comprises an upper layer and a lower layer,
the upper layer comprises the first inorganic particle, and
the lower layer comprises the second inorganic particle.

5. The display protective layer of claim 1, wherein the hard coating layer and the anti-reflective layer are in direct contact with each other.

6. The display protective layer of claim 1, wherein
the anti-reflective layer comprises an upper layer and a lower layer,
the upper layer comprises the first inorganic particle,
the lower layer comprises the second inorganic particle, and
the hard coating layer and the lower layer are in direct contact with each other.

7. The display protective layer of claim 1, wherein the first inorganic particle comprises hollow inorganic particles.

8. The display protective layer of claim 1, wherein the first inorganic particle comprises a metalloid or an oxide thereof.

9. The display protective layer of claim 1, wherein the first inorganic particle comprises B, Si, Ge, As, Sb, Te, a combination thereof, or an oxide thereof.

10. The display protective layer of claim 1, wherein the second inorganic particle comprises a transition metal or an oxide thereof.

11. The display protective layer of claim 1, wherein the second inorganic particle comprises Zr or an oxide thereof.

12. The display protective layer of claim 1, wherein the first inorganic particle has a diameter in a range of about 1 nm to about 200 nm.

13. The display protective layer of claim 1, wherein the second inorganic particle has a diameter in a range of about 0.5 nm to about 100 nm.

14. The display protective layer of claim 1, wherein a thickness of the anti-reflective layer is in a range of about 150 nm to about 500 nm.

15. The display protective layer of claim 1, wherein a surface energy of an upper portion of the anti-reflective layer is less than or equal to about 25 dyne/cm.

16. The display protective layer of claim 1, wherein a specular component included (SCI) of the anti-reflective layer is less than or equal to about 0.30.

17. An electronic apparatus comprising the display protective layer of claim 1.

18. A hollow inorganic particle having a refractive index in a range of about 1.10 to about 1.40,
wherein a surface of the hollow inorganic particle is coated with a fluorine-containing moiety.

19. The hollow inorganic particle of claim 18, comprising a metalloid or an oxide thereof.

20. The hollow inorganic particle of claim 18, wherein a diameter of the hollow inorganic particle is in a range of about 1 nm to about 200 nm.
